(19) United States
(12) Patent Application Publication
(10) Pub. No.: US 2005/0189972 A1
(43) Pub. Date: Sep. 1, 2005

(54) System and method for achieving low power standby and fast relock for digital phase lock loop

(76) Inventors: Tim Foo, Garland, TX (US); Baher S. Haroun, Allen, TX (US); Hugh T. Mair, Fairview, TX (US)

Correspondence Address: TEXAS INSTRUMENTS INCORPORATED, P O BOX 655474, M/S 3999, DALLAS, TX, 75265, US

(21) Appl. No.: 10/788,709

(22) Filed: Feb. 27, 2004

(51) Int. Cl. H03L 7/06

(52) U.S. Cl. 327/156

(57) ABSTRACT

A digital phase lock loop (DPLL) system and method employ digital loop control and a digital controller to drive the DPLL oscillator with fast re-lock capability. The DPLL optionally uses low power retention flops to implement low power and fast interrupt services.

### BACKGROUND OF THE INVENTION

1. Field of the Invention

This invention relates generally to digital phase lock loops, and more particularly to a technique for achieving digital phase lock loop low standby power consumption and fast relock time upon wake-up from the standby mode.

2. Description of the Prior Art

Power consumption in handheld devices is one of the foremost concerns of system as well as ASIC designers. As the result, certain hardware modules are shut off when they are not in use by removing the synthesized clock to the associated blocks. In modern high speed CMOS technology, quiescent leakage current can no longer be ignored. In order to completely shut off or significantly reduce the quiescent current to these blocks when the clocks are removed, any power supply to the blocks may also be removed. These blocks have built in retention capability in their memory elements such as flip-flops and non-volatile memory so that the active state values can be preserved through a secondary supply while the main power supply is shutoff. These modules however, are required to come alive almost immediately when their services are needed. Starting from the PLL (phase lock loop), synthesized clocks are required to return immediately so the system does not incur any latency in services including any hardware or software services.

In view of the foregoing, a need exists for a technique for achieving digital phase lock loop low standby power consumption and fast relock time upon wake-up from the standby mode.

### SUMMARY OF THE INVENTION

To meet the above and other objectives, the present invention provides a digital phase lock loop (DPLL) technique that use digital loop control and a digital controller to drive the DPLL oscillator with fast re-lock capability.

According to one embodiment, a method for controlling a digital phase lock loop (DPLL) comprises the steps of:
providing a DPLL having a digital controlled oscillator (DCO);
storing the present active state of the DPLL; and
removing primary power to the DPLL subsequent to storing its present active state.

According to another embodiment, a digital phase lock loop (DPLL) comprises:
a digital controlled oscillator (DCO);
a digital controller operational to generate DCO control codes;
a reference clock;
a phase frequency detector (PFD);
a time digitizer operational to convert phase error between reference and feedback clocks into a digital control code such that the digital controller is controlled there from;
a feedback loop from the DCO output to generate the feedback clock to the PFD input; and
algorithmic control software, wherein the DPLL operates in response to the algorithmic control software to store the present active state of the DPLL and remove primary power to the DPLL subsequent to storing its present active state.

### BRIEF DESCRIPTION OF THE DRAWINGS

Other aspects and features of the present invention and many of the attendant advantages of the present invention will be readily appreciated as the invention becomes better understood by reference to the following detailed description when considered in connection with the accompanying drawings in which like reference numerals designate like parts throughout the figures thereof and wherein:

FIG. 1 is a block diagram illustrating a wide band general purpose DPLL suitable for use with a low power retention flop to implement low power and fast interrupt services;

FIG. 2 illustrates a DPLL state machine diagram with low power retention, digital controlled oscillator (DCO) frequency rollback and normalized frequency lock detection according to one embodiment of the present invention;

FIG. 3 is a schematic diagram illustrating clock gating and a power header switch according to one embodiment of the present invention;

FIG. 4 is diagram illustrating DCO frequency rollback and relock at different voltage and temperature conditions;

FIG. 5 is a timing diagram illustrating normalized phase and frequency lock detection associated with the embodiments shown in FIGS. 1-3; and

FIG. 6 is a waveform diagram showing simulation results associated with proper retention and relock operations for the embodiments shown in FIGS. 1-3.

While the above-identified drawing figures set forth particular embodiments, other embodiments of the present invention are also contemplated, as noted in the discussion. In all cases, this disclosure presents illustrated embodiments of the present invention by way of representation and not limitation. Numerous other modifications and embodiments can be devised by those skilled in the art which fall within the scope and spirit of the principles of this invention.

### DETAILED DESCRIPTION OF THE PREFERRED EMBODIMENTS

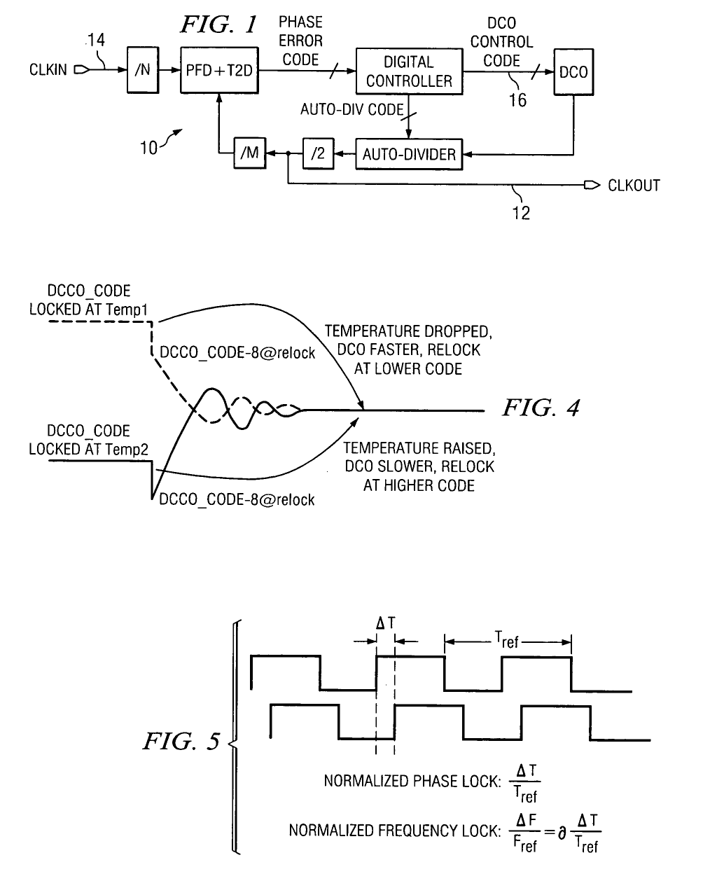

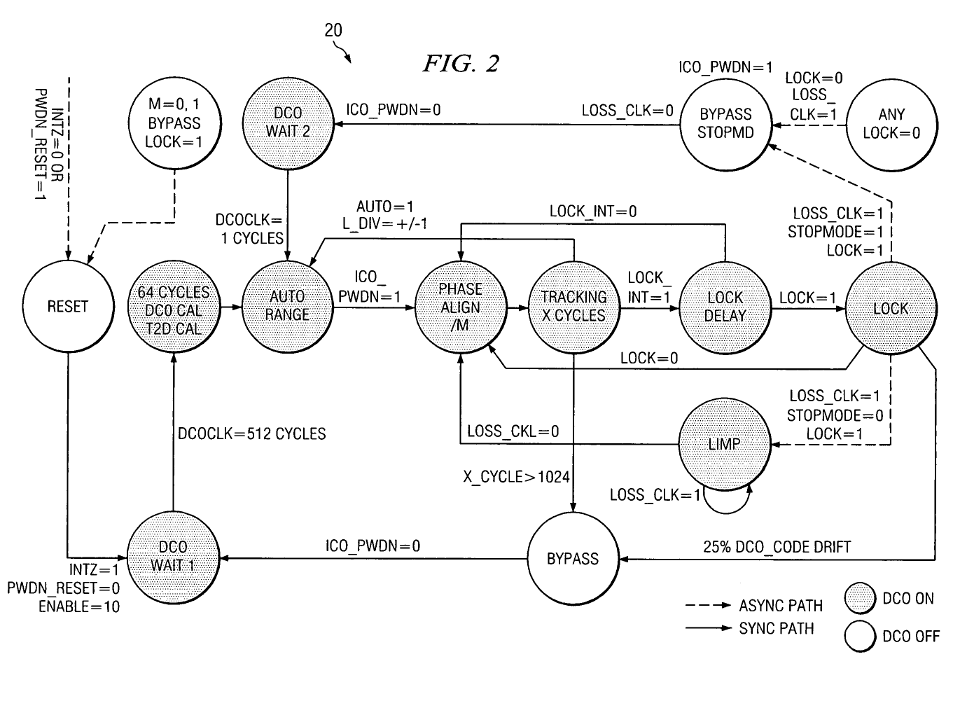

Looking now at FIG. 1, a block diagram illustrates a wide band general purpose digital phase lock look (DPLL) 10 suitable for use, for example, with a low power retention flop to implement low power and fast interrupt services according to one embodiment. Such a DPLL solution provides an extremely low power standby mode while still being able to wake up and relock to the previously locked frequency in a minimum amount of time. More specifically, the wide band general purpose DPLL 10 and low power retention flops are combined in a manner to solve the most critical specification in today's handheld devices: low power and fast interrupt services. Retention flops therefore provide one optional means to allow the state of the DPLL 10 to be saved before the main power supply to the DPLL 10 is shut off so power can be conserved for both the DPLL 10 and the hardware modules supplied by the DPLL synthesized clock. After the power supply is re-asserted, the state of the DPLL 10 before power down is restored. A low power standby mode is introduced into the DPLL 10 to keep only the small bias alive when all the digital elements are in retention. Once the DPLL 10 is required to wake up, two additional techniques described in further detail herein below with reference to FIGS. 2-6 are implemented to achieve fast relock.

First, an extremely accurate phase alignment operation is implemented to allow the digital controlled oscillator (DCO) output feedback clock to be aligned to the reference clock 14 and at the same time guarantee the DCO output clock frequency is exactly the same as before the DPLL was shut off, assuming the voltage and temperature remain unchanged. There can be no guarantee however that such an assumption will always hold true. Therefore, this phase alignment operation rolls back the DCO code 16 to commence at a slightly lower clock frequency to which it previously locked. This operation is critical to provide some safe guard for preventing the DCO output clock 12 from overshooting or starting at a much higher frequency due to temperature and or voltage changes.

Secondly, a normalized frequency lock detection circuit is implemented to determine if the targeted output frequency has been achieved. Normalized frequency lock detection guarantees the locked frequency is within a certain percentage of the desired output frequency, which covers a wide range based on the general purpose DPLL architecture.

The techniques described above provide were found by the present inventors to provide handheld device designers with a powerful advantage to pursue extremely low power applications without scarifying the functionality and user friendliness of future handheld appliances. Looking now at FIG. 2, a detailed state machine diagram 20 is shown for controlling the low power DPLL 10 according to one embodiment. Since the power supply to the state machine registers is the heart of the DPLL 10, the primary power supply to the state machine registers is also removed, while the state machine register values are preserved with a secondary power supply having extremely low leakage transistors.

Theory of Operation

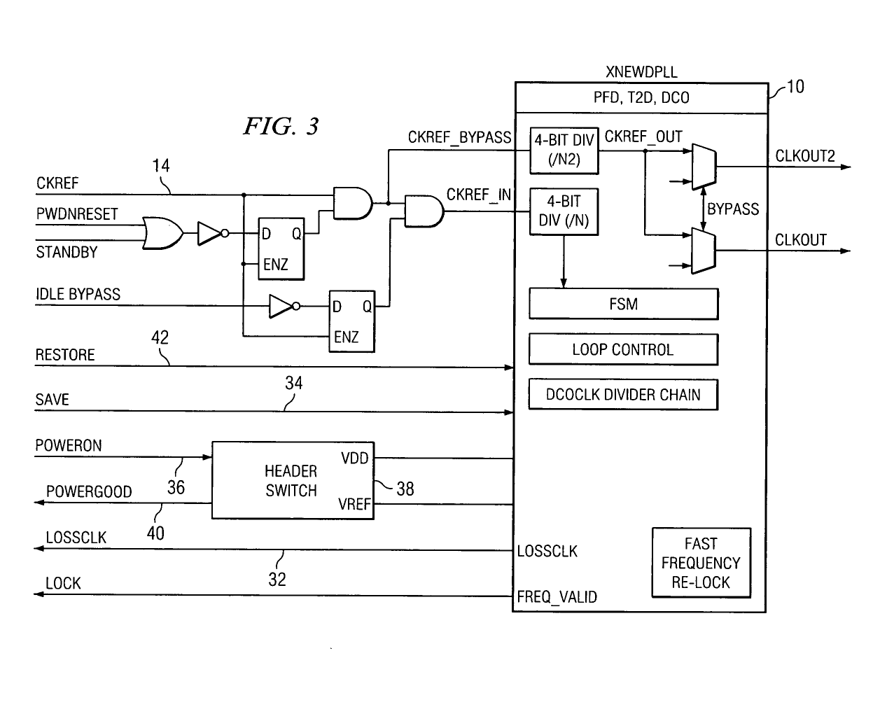

Keeping the foregoing discussion in mind, the theory of operation is now described herein below with reference to FIGS. 3-6. FIG. 3 is a simplified schematic diagram showing the power control and clock gating of the DPLL 10. When the SOC (system on a chip), described with reference to FIGS. 1-6, decides to shut down the synthesized clock to a block, the reference clock 14 to the DPLL 10 is gated. The DPLL 10 internally detects the loss of reference clock 14 and replies with a LOSSCLK signal 32. Upon the LOSSCLK acknowledge, SOC asserts the SAVE signal 34 to put all registers in the DPLL 10 into its retention mode. It then follows with removal of POWERON 36 which shuts off the main power supply for the DPLL 10 through a power (header) switch 38. Power supplies to the digital blocks in the DPLL 10 are shut off excepting the retention elements in registers with extremely low leakage current that are maintained through a secondary power supply. Most preferably, any analog blocks power supply can be completely or partially shutoff depending on a programmable bit. When both the analog and digital blocks power supplies are shutoff, the current consumption in one embodiment during power down mode was found to be approximately 100 nA.

DCO Frequency Rollback and Phase Alignment

Once the SOC has decided to return the synthesized clock to certain blocks, a proper sequence must be followed to power up the DPLL 10 in order to guarantee the retention registers recover their states properly before return to lock. The POWERON signal 36 must be first reasserted. Once this condition has been acknowledged by the POWERGOOD signal 40, the assertion of RESTORE signal 42 will follow. Once the power is restored for all registers in DPLL 10, the original state of the DPLL 10 before going into retention can be restored as RESTORE signal 42 is asserted. During this time, the reference clock 14 remains inactive. The reference clock 14 returns after the removal of RESTORE signal 42, and in response the DPLL state machine restarts from the state held prior to going into retention. Important tasks carried out during this process can be described as follows. First, LOSSCLK signal 32 is de-asserted to acknowledge the return of reference clock 14. Second, the DAC code that controls the DCO oscillation is rolled back by a few codes; and lastly the analog blocks are powered up again. When the DCO 12 return to oscillation again, it will go through an accurate phase alignment process shown in FIG. 2, so the feedback clock will restart closely in phase with the reference clock 14. The phase alignment process also guarantees the feedback clock always wake up lagging the reference clock 14 so that the loop control will respond with an upward frequency correction.

Since there is no limit on how long the DPLL 10 can be set in the retention mode, both the voltage and temperature of operation can vary significantly while in its retention mode. A DCO with good PSRR will not be affected by slight voltage changes; temperature changes however, could affect the DCO oscillation frequency beyond the tolerate range of the SOC design. DCO frequency rollback along with the phase alignment process described herein above restart the DCO at a lower frequency, thus minimizing the risk of DCO frequency overshoot during the re-locking process. FIG. 4 shows the DPLL 10 regaining lock from retention in different temperature variation scenarios. The present inventors have discovered the DPLL described with reference to FIGS. 1-6 provides a constant damping factor for the loop that also reduces the frequency overshoot while regaining lock.

Normalized Frequency Lock Detection

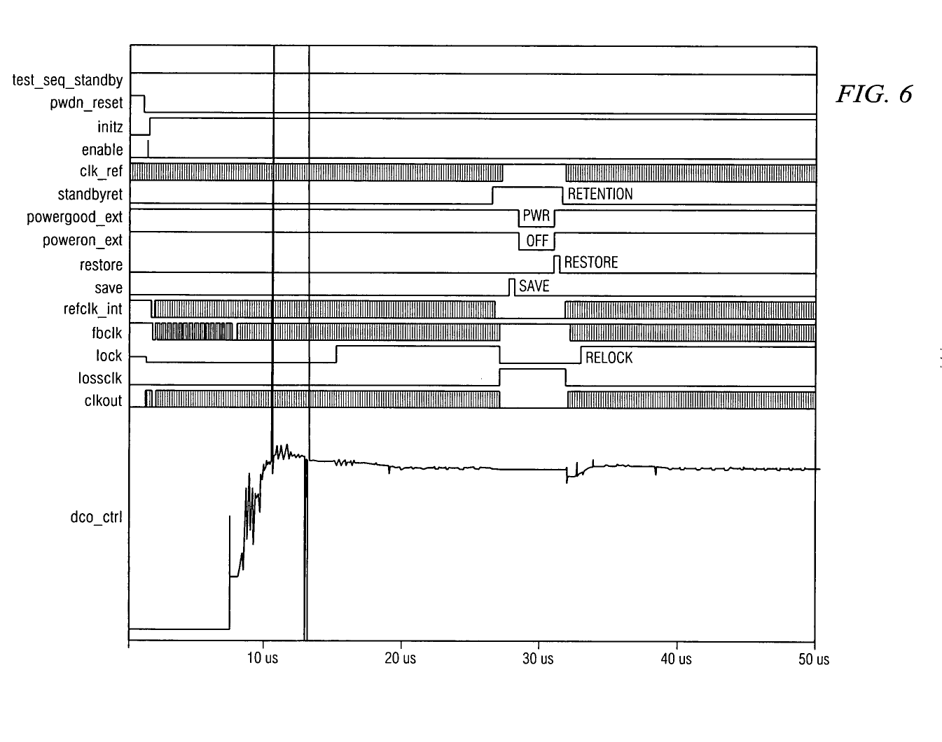

Lock detection is a highly desirable feature in PLLs. The most appropriate criteria to measure the locking of the loop is the phase error between the reference and feedback clocks. In a DPLL, the phase error between these two clocks is converted into digital codes through a time digitizer circuit. In order to provide meaningful lock criteria across a wide range of clock frequencies, a normalization of the phase error code is necessary. The loop normalization technique used in the DPLL 10 can be applied to the normalization of the phase lock detection effortlessly. The frequency lock detection is a simple derivation of the phase lock as shown in FIG. 5. FIG. 6 is a waveform diagram showing simulation results associated with proper retention and relock operations for the embodiments described herein before with reference to FIGS. 1-5.

In summary explanation, a DPLL with an extremely low power retention mode prolongs the battery life for wireless and handheld devices. Proper clock gating, retention register and power switch methodology allows the DPLL to be powered down and restarted seamlessly to regain frequency and phase locks. Carefully designed DCO frequency rollback, phase alignment and normalized frequency lock detection described herein before allows aggressive handheld systems design that consume low power without scarifying the functionality and user-friendliness associated with future applications.

In view of the above, it can be seen the present invention presents a significant advancement in the art of digital phase lock loops. Further, this invention has been described in considerable detail in order to provide those skilled in the DPLL art with the information needed to apply the novel principles and to construct and use such specialized components as are required. In view of the foregoing descriptions, it should further be apparent that the present invention represents a significant departure from the prior art in construction and operation. However, while particular embodiments of the present invention have been described herein in detail, it is to be understood that various alterations, modifications and substitutions can be made therein without departing in any way from the spirit and scope of the present invention, as defined in the claims which follow.

1. A method for controlling a digital phase lock loop (DPPL), the method comprising the steps of:
providing a DPLL having a digital controlled oscillator (DCO);
storing the present active state of the DPLL; and
removing primary power to the DPLL subsequent to storing its present active state.

2. The method according to claim 1, wherein the step of storing the present active state of the DPLL comprises placing selective DPLL digital elements having register retention capability into a low power standby mode.

3. The method according to claim 1, further comprising the steps of:
reasserting the primary power to the DPLL; and
restoring the present active state of the DPLL.

4. The method according to claim 3, wherein the step of restoring the present active state of the DPLL comprises the steps of:
aligning a DCO feedback clock with a reference clock; and
simultaneously with aligning the DCO feedback clock with a reference clock, controlling the DCO such that its output clock frequency is substantially identical with its frequency prior to removal of the primary DPLL power.

5. The method according to claim 4, wherein the step of controlling the DCO such that its output clock frequency is substantially identical with its frequency prior to removal of the primary DPLL power, comprises the steps of:
rolling back a DCO control code such that the DCO restarts at a slightly lower clock frequency than the frequency at which the DCO most previously was locked; and
detecting if and when a targeted DCO output clock frequency has been achieved.

6. The method according to claim 5, wherein the step of detecting if and when a targeted DCO output clock frequency has been achieved comprises the step of detecting a normalized frequency lock to determine whether the targeted DCO output clock frequency is locked within a desired percentage of a desired DCO output clock frequency.

7. A digital phase lock loop (DPLL) comprising:
a digital controlled oscillator (DCO);
a digital controller operational to generate DCO control codes;
a reference clock;
a phase frequency detector (PFD);
a time digitizer operational to convert phase error between reference and feedback clocks into a digital control code such that the digital controller is controlled there from;
a feedback loop from the DCO output to generate the feedback clock to the PFD input; and
algorithmic control software, wherein the DPLL operates in response to the algorithmic control software to store the present active state of the DPLL and remove primary power to the DPLL subsequent to storing its present active state.

8. The DPLL according to claim 7, wherein the DPLL further operates in response to the algorithmic control software to reassert the primary power to the DPLL and restore the present active state of the DPLL.

9. The DPLL according to claim 7, wherein the DPLL further operates in response to the algorithmic control software to reassert the primary power to the DPLL, align the DCO output clock with the reference clock and simultaneously control the DCO such that its output clock frequency is substantially identical with its frequency prior to removal of the primary DPLL power.

10. The DPLL according to claim 7, wherein the DPLL further operates in response to the algorithmic control software to reassert the primary power to the DPLL, align the DCO output clock with the reference clock and simultaneously roll back the DCO control code such that the DCO restarts at a slightly lower clock frequency than the frequency at which the DCO most previously was locked and detect if and when a targeted DCO output clock frequency has been achieved.

11. The DPLL according to claim 7, wherein the DPLL further operates in response to the algorithmic control software to reassert the primary power to the DPLL, align the DCO output clock with the reference clock and simultaneously roll back the DCO control code such that the DCO restarts at a slightly lower clock frequency than the frequency at which the DCO most previously was locked and detect a normalized frequency lock to determine whether the targeted DCO output clock frequency is locked within a desired percentage of a desired DCO output clock frequency.
